(19) United States
(12) Patent Application Publication
(10) Pub. No.: US 2026/0331438 A1
(43) Pub. Date: Oct. 22, 2026

(54) PLASMA PROCESSING APPARATUS

(71) Applicant: TOKYO ELECTRON LIMITED, Tokyo (JP)

(72) Inventors: Yoshinori SUZUKI, Tokyo (JP); Toshihiro TSURUTA, Tokyo (JP)

(21) Appl. No.: 19/707,895

(22) Filed: Jun. 15, 2026

Related U.S. Application Data
(63) Continuation of application No. PCT/JP2024/039396, filed on Nov. 6, 2024.

(30) Foreign Application Priority Data
Dec. 28, 2023 (JP) 2023-223167

(51) Int. Cl. H01J 37/32

(52) U.S. Cl. CPC H01J 37/32697; H01J 37/32174; H01J 37/32449; H01J 37/32642; H01J 2237/334

(57) ABSTRACT

A plasma processing apparatus includes a chamber; a substrate support; an edge ring; an upper electrode; a first gas supply; an RF power source; a DC power source configured to apply a DC voltage to the edge ring; a first counter configured to count a first time according to an operation time of the RF power source and to reset the first time by replacing the upper electrode; a second counter configured to count a second time according to the operation time of the RF power source and to reset the second time by replacing the edge ring; a first processor configured to stepwisely change at least one of the RF power and the first gas according to the first time; and a second processor configured to stepwisely change the DC voltage according to the second time.

### CROSS-REFERENCE TO RELATED APPLICATIONS

This application is bypass continuation of International Patent Application PCT/JP2024/039396, filed Nov. 6, 2024, which claims benefit of priority from Japanese Patent Application 2023-223167, filed Dec. 28, 2023, the contents of both of which are incorporated herein by reference.

### BACKGROUND

### Field

Exemplary embodiments of the present disclosure relate to a plasma processing apparatus.

### Description of Related Art

As a technique for suppressing a change in a tilt shape over time that occurs in an edge region of a substrate, there is a technique described in JP 2021-39924

The present disclosure provides a technique that can reduce an influence on plasma processing of a substrate due to the wear of components in a chamber of a plasma processing apparatus.

### SUMMARY

A plasma processing apparatus in one exemplary embodiment of the present disclosure includes: a chamber; a substrate support placed within the chamber and including a lower electrode; an edge ring placed to surround a substrate on the substrate support; an upper electrode placed above the substrate support; a first gas supply configured to supply a first gas into the chamber; an RF power source configured to supply RF power to the upper electrode or the lower electrode to generate plasma from the first gas within the chamber; a DC power source configured to apply a DC voltage to the edge ring; a first counter configured to count a first time according to an operation time of the RF power source and to reset the first time by replacing the upper electrode; a second counter configured to count a second time according to the operation time of the RF power source and to reset the second time by replacing the edge ring; a first processor configured to stepwisely change at least one of the RF power and the first gas according to the first time; and a second processor configured to stepwisely change the DC voltage according to the second time.

### BRIEF DESCRIPTION OF DRAWINGS

FIG. 1 is a view illustrating an example of a configuration of a plasma processing system.

FIG. 2 is a view illustrating an example of a configuration of a plasma processing apparatus in a first embodiment.

FIG. 3 is a view illustrating an example of a configuration of a controller.

FIG. 4 is a view illustrating an example of a replacement cycle and a count time for an upper electrode and an edge ring.

FIG. 5 is a view illustrating an example of stepwisely changing RF power according to a first time.

FIG. 6 is a view illustrating an example of examples of stepwisely changing a flow rate of a first gas according to the first time.

FIG. 7 is a view illustrating an example of examples of stepwisely changing a DC voltage according to a second time.

FIG. 8 is a view illustrating an example of a configuration of a plasma processing apparatus in a second embodiment.

FIG. 9 is a view illustrating an example of a configuration of a controller.

FIG. 10 is a view illustrating an example of a replacement cycle and a count time for an upper electrode, an edge ring, and an upper annular member.

FIG. 11 is a view illustrating an example of examples of stepwisely changing a flow rate of a second gas according to a third time.

FIG. 12 is a view illustrating an example of examples of stepwisely changing first and second power values according to the third time.

### DESCRIPTION OF EMBODIMENTS

The embodiments of this disclosure will be described below.

In one exemplary embodiment, there is provided a plasma processing apparatus including: a chamber; a substrate support placed within the chamber and including a lower electrode; an edge ring placed to surround a substrate on the substrate support; an upper electrode placed above the substrate support; a first gas supply configured to supply a first gas into the chamber; an RF power source configured to supply RF power to the upper electrode or the lower electrode to generate plasma from the first gas within the chamber; a DC power source configured to apply a DC voltage to the edge ring; a first counter configured to count a first time according to an operation time of the RF power source and to reset the first time by replacing the upper electrode; a second counter configured to count a second time according to the operation time of the RF power source and to reset the second time by replacing the edge ring; a first processor configured to stepwisely change at least one of the RF power and the first gas according to the first time; and a second processor configured to stepwisely change the DC voltage according to the second time.

In one exemplary embodiment, a replacement cycle of the edge ring is different from a replacement cycle of the upper electrode.

In one exemplary embodiment, the first processor is configured to stepwisely increase the RF power according to the first time, and the second processor is configured to stepwisely increase the DC voltage according to the second time.

In one exemplary embodiment, the first processor is configured to stepwisely decrease a flow rate of the first gas according to the first time.

In one exemplary embodiment, the plasma processing apparatus further includes: a second gas supply, in which the upper electrode has a central region and an annular region in a plan view, the first gas supply is configured to supply the first gas into the chamber via the central region, and the second gas supply is configured to supply a second gas into the chamber via the annular region.

In one exemplary embodiment, the plasma processing apparatus further includes: an annular member placed to surround the upper electrode or the edge ring; a third counter configured to count a third time according to the operation time of the RF power source and to reset the third time by replacing the annular member; and a third processor configured to stepwisely change a flow rate of the second gas according to the third time.

In one exemplary embodiment, the plasma processing apparatus further includes: an annular member placed to surround the upper electrode; and a third counter configured to count a third time according to the operation time of the RF power source and to reset the third time by replacing the annular member, in which the first processor is configured to stepwisely change the RF power according to the first time and the third time.

In one exemplary embodiment, the first processor is configured to add a first power value according to the first time and a second power value according to the third time to a power level of the RF power.

In one exemplary embodiment, the first processor is configured to add a first power value to a power level of the RF power in each step in a first section, and to add a second power value different from the first power value to the power level of the RF power in each step in a second section.

In one exemplary embodiment, the first processor is configured to maintain a constant power level in a third section.

In one exemplary embodiment, the second processor is configured to add a first voltage value to a voltage level of the DC voltage in each step in a first section, and to add a second voltage value different from the first voltage value to the voltage level of the DC voltage in each step in a second section.

In one exemplary embodiment, the second processor is configured to maintain a constant voltage level in a third section.

In one exemplary embodiment, the first processor is configured to subtract a first flow rate value from a flow rate of the first gas in each step in a first section, and to subtract a second flow rate value different from the first flow rate value from the flow rate of the first gas in each step in a second section.

In one exemplary embodiment, the first processor is configured to maintain a constant flow rate in a third section.

In one exemplary embodiment, there is provided a plasma processing apparatus including: a chamber; an RF power source configured to generate RF power to generate plasma within the chamber; a first consumable component placed within the chamber; a second consumable component placed within the chamber; a first counter configured to count a first time according to an operation time of the RF power source and to reset the first time by replacing the first consumable component; a second counter configured to count a second time according to the operation time of the RF power source and to reset the second time by replacing the second consumable component; a first processor configured to stepwisely change a first process parameter according to the first time; and a second processor configured to stepwisely change a second process parameter according to the second time.

In one exemplary embodiment, a replacement cycle of the first consumable component is different from a replacement cycle of the second consumable component.

In one exemplary embodiment, the plasma processing apparatus further includes: a third consumable component placed within the chamber; and a third counter configured to count a third time according to the operation time of the RF power source and to reset the third time by replacing the third consumable component, in which the first processor is configured to add or subtract a first value according to the first time and a second value according to the third time to or from the first process parameter.

In one exemplary embodiment, the first processor is configured to add or subtract a first value to or from the first process parameter in each step in a first section, and to add or subtract a second value to or from the first process parameter in each step in a second section.

In one exemplary embodiment, the second processor is configured to add or subtract a first value to or from the second process parameter in each step in a first section, and to add or subtract a second value to or from the second process parameter in each step in a second section.

In one exemplary embodiment, there is provided a plasma processing apparatus including: a chamber; an RF power source configured to generate RF power to generate plasma within the chamber; a consumable component placed within the chamber; a counter configured to count a first time according to an operation time of the RF power source and to reset the first time by replacing the consumable component; and a processor configured to stepwisely change a first process parameter according to the first time, in which the processor is configured to add or subtract a first value to or from the first process parameter in each step in a first section, and to add or subtract a second value to or from the first process parameter in each step in a second section.

Each embodiment of the present disclosure will be described in detail below with reference to the drawings. Furthermore, identical or similar elements in each drawing are denoted by the same reference numeral, and redundant explanations are omitted. Unless otherwise specified, positional relationships (up, down, left, right, etc.) will be explained based on the positional relationships illustrated in the drawings. The dimensional ratios illustrated in the drawings do not represent actual ratios, and actual ratios are not limited to those illustrated.

### First Embodiment

### <Example of Plasma Processing System>

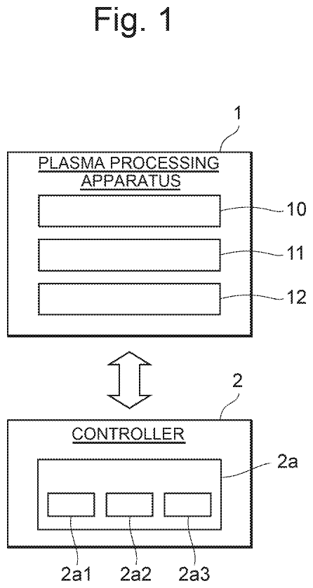

FIG. 1 is a view for explaining an example of a configuration of a capacitively-coupled plasma processing system. In one embodiment, the plasma processing system includes a plasma processing apparatus 1 and a controller 2. The plasma processing system is an example of a substrate processing system and the plasma processing apparatus 1 is an example of a substrate processing apparatus. The plasma processing apparatus 1 includes a plasma processing chamber 10, a substrate support 11 and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected the gas supply 20 to be described below, and the gas exhaust port is connected to the exhaust system 40 to be described below. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be Capacitive Coupled Plasma (CCP), Inductively Coupled Plasma (ICP), Electron-Cyclotron-resonance (ECR) plasma, Helicon Wave Plasma (HWP) or Surface Wave Plasma (SWP). Further, various types of plasma generator including Alternative Current (AC) plasma generator and Direct Current (DC) plasma generator may be used. In one embodiment, an AC signal (AC power) used in the AC plasma generator may have a frequency in the range of 100 kHz to 10 GHz. Accordingly, an AC signal may include Radio Frequency (RF) signal and Microwave signal. In one embodiment, an RF signal may have a frequency in the range of 100 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

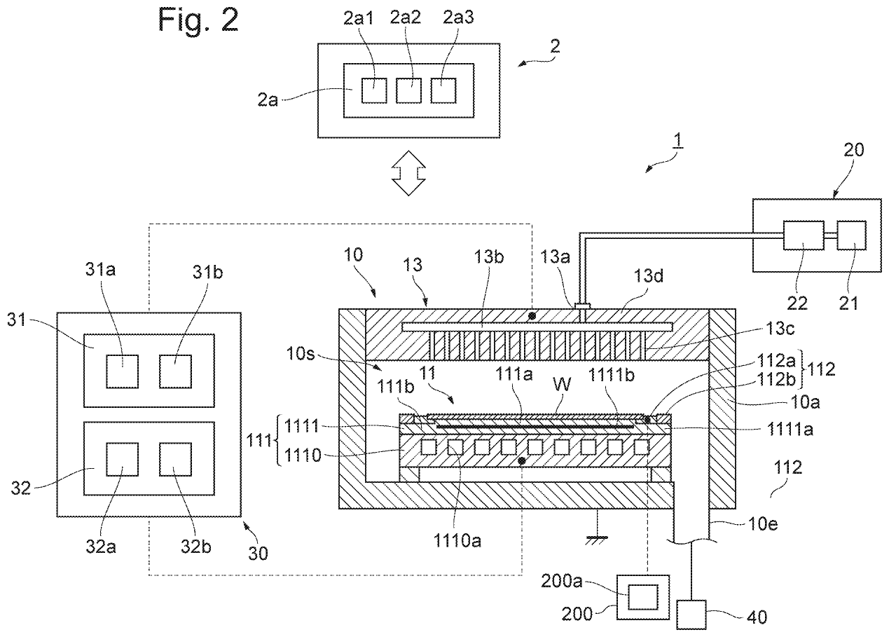

Hereinafter, an example of the configuration example of a plasma processing apparatus will be described. FIG. 2 is a view for explaining an example of a configuration of a capacitively-coupled plasma processing apparatus.

The plasma processing system includes a capacitively-coupled plasma processing apparatus 1 and a controller 2. The capacitively-coupled plasma processing apparatus 1 includes a plasma processing chamber 10, a gas supply 20, a power source 30, and an exhaust system 40. Further, the plasma processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body portion 111 has a central region 111a for supporting the substrate W and an annular region 111b for supporting the ring assembly 112. The wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has a central region 111a. In one embodiment, the ceramic member 1111a also has an annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where the bias RF signal and/or the DC signal to be described later are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between the rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) to at least one lower electrode and/or at least one upper electrode. As a result, plasma is formed from at least one processing gas supplied into the plasma processing space 10s. Accordingly, the RF power source 31 may function as at least a portion of the plasma generator 12. Further, by supplying the bias RF signal (bias signal) to the at least one lower electrode, a bias potential (bias power) is generated in the substrate W, making it possible to draw ion components in the formed plasma into the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, the sequence of voltage pulses is applied to at least one lower electrode and/or at least one upper electrode. The voltage pulse may have a pulse waveform of a rectangle, a trapezoid, a triangle or a combination thereof. In one embodiment, a waveform generator for generating a sequence of voltage pulses from the DC signal is connected between the first DC generator 32a and at least one lower electrode. Accordingly, the first DC generator 32a and the waveform generator configure a voltage pulse generator. In a case where the second DC generator 32b and the waveform generator configure the voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

In the plasma processing apparatus 1 described above, the ring assembly 112 includes an edge ring 112a and a cover ring 112b. In one embodiment, the cover ring 112b is placed to surround a periphery of the edge ring 112a. In one embodiment, the plasma processing apparatus 1 has a DC power source 200 configured to apply a DC voltage to the edge ring 112a. The DC power source 200 may be included in the power source 30. The DC power source 200 includes a DC generator 200a. In one embodiment, the DC generator 200a is electrically connected to the edge ring 112a via at least one conductive member and is configured to generate a DC signal. The DC signal may be pulsed in the same manner as the first and second DC signals described above. The generated DC signal is applied to the edge ring 112a via at least one conductive member.

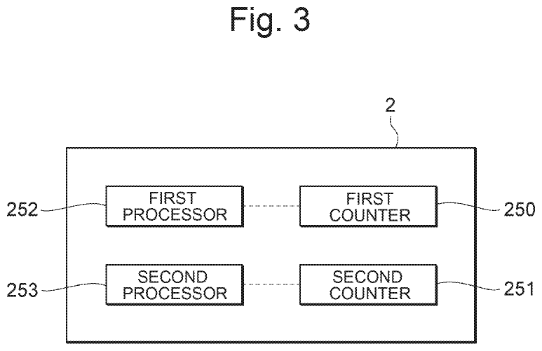

As illustrated in FIG. 3, in one embodiment, the plasma processing apparatus 1 further includes a first counter 250, a second counter 251, a first processor 252, and a second processor 253. The first counter 250, the second counter 251, the first processor 252, and the second processor 253 may be included in the controller 2.

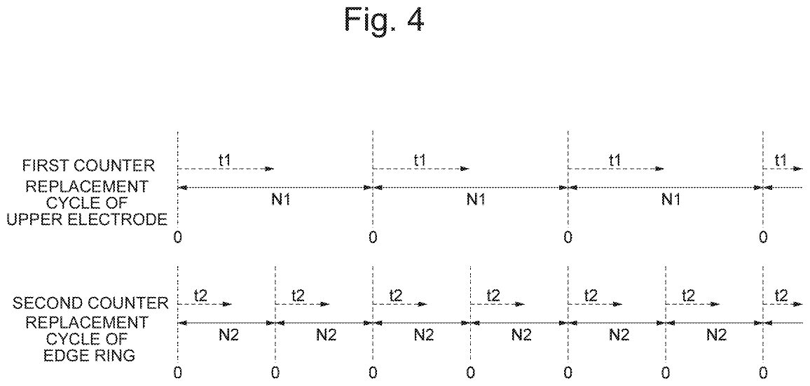

As illustrated in FIG. 4, the first counter 250 is configured to count a first time t1 according to the operation time (running time) of the RF power source 31 and to reset the first time t1 by replacing the upper electrode 13d of the shower head 13. In other words, the first time t1 of the first counter 250 is reset each time the upper electrode 13d is replaced, and then is counted from a reference value according to the operation time of the RF power source 31. The reference value may be zero. The operation time of the RF power source 31 may be obtained in various ways. For example, the operation time of the RF power source 31 may be obtained by a timer built into the RF power source 31. That is, the operation time of the RF power source 31 can be said to be the time during which the RF power source 31 supplies RF power to the upper electrode 13d or the lower electrode to generate plasma from the first gas in the chamber 10.

The second counter 251 is configured to count a second time t2 according to the operation time of the RF power source 31 and to reset the second time t2 by replacing the edge ring 112a. That is, the second time t2 of the second counter 251 is reset each time the edge ring 112a is replaced, and then is counted from the reference value according to the operation time of the RF power source 31. The reference value may be zero.

A replacement cycle N2 of the edge ring 112a is different from a replacement cycle N1 of the upper electrode 13d. In one embodiment, the replacement cycle N2 of the edge ring 112a is shorter than the replacement cycle N1 of the upper electrode 13d. In this case, the second time t2 counted by the second counter 251 is reset at a shorter interval than the first time t1 counted by the first counter 250.

In one embodiment, the first processor 252 is configured to stepwisely change at least one of the RF power supplied to the upper electrode 13d or the lower electrode by the RF power source 31 and the flow rate of the first gas supplied to the chamber 10 by the gas supply 20 according to the first time t1.

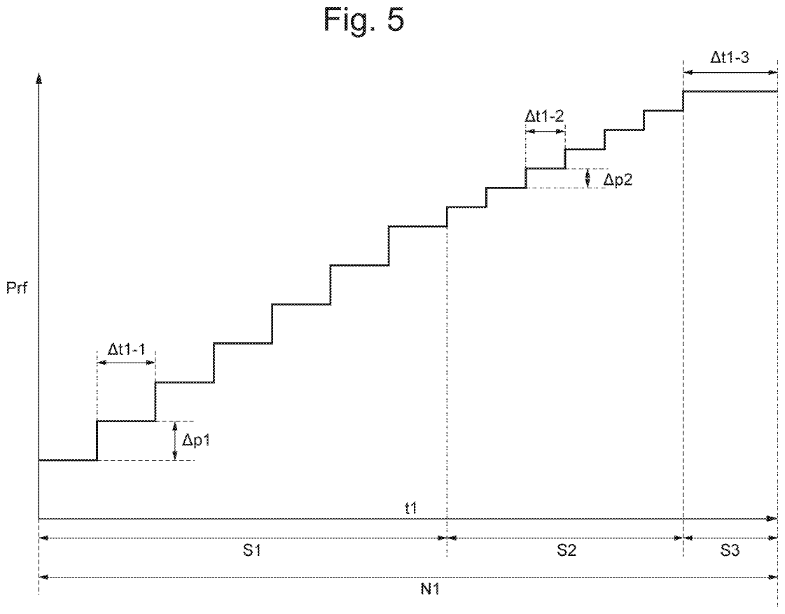

In the example illustrated in FIG. 5, the first processor 252 is configured to stepwisely increase the RF power Prf according to the first time t1. Specifically, the first processor 252 is configured to add a first power value Δp1 to the power level of the RF power Prf in each step in the first section S1. The first processor 252 is configured to add a second power value Δp2 different from the first power value Δp1 to the power level of the RF power Prf in each step in the second section S2. The first processor 252 is configured to maintain a constant power level in the third section S3. In each of the sections S1 to S3, the power values Δp1 and Δp2 that increase in each step, the times (lengths) Δt1-1, Δt1-2, and Δt1-3 of each step, and the number of steps may be set, respectively. A combined time of the sections S1 to S3 may be the replacement cycle N1 of the upper electrode 13d. The number of the sections is not limited to three, and the number of sections may be one or two, or four or more.

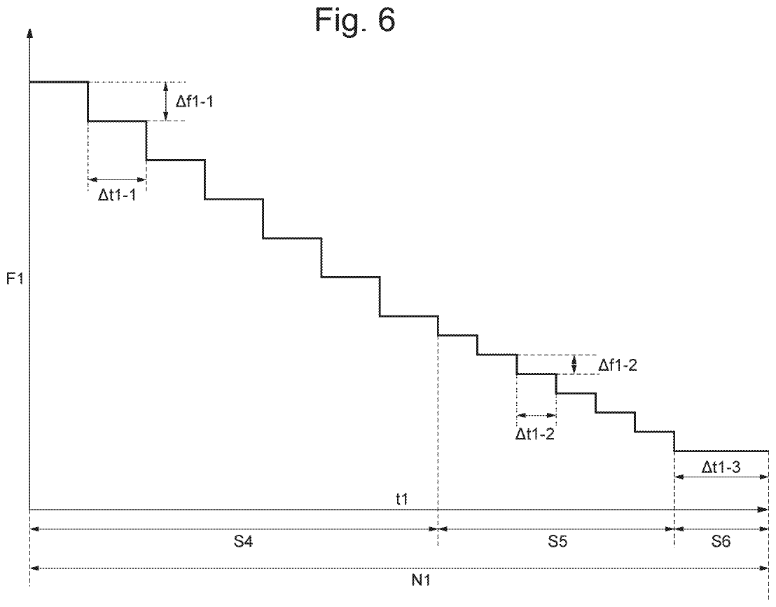

In the example illustrated in FIG. 6, the first processor 252 is configured to stepwisely decrease the flow rate F1 of the first gas according to the first time t1. Specifically, the first processor 252 is configured to subtract a first flow rate value Δf1-1 from the flow rate F1 of the first gas in each step in the first section S4. The first processor 252 is configured to subtract a second flow rate value Δf1-2 different from the first flow rate value Δf1-1 from the flow rate F1 of the first gas in each step in the second section S5. The first processor 252 is configured to maintain a constant flow rate in the third section S6. In each of the sections S4 to S6, the flow rate values Δf1-1 and Δf1-2 to be subtracted in each step, the times (lengths) Δt1-1, Δt1-2, and Δt1-3 of each step, and the number of steps may be set, respectively. A combined time of the sections S4 to S6 may be the replacement cycle N1 of the upper electrode 13d. The number of sections is not limited to three and the number of sections may be one or two, or four or more.

In one embodiment, the second processor 253 is configured to stepwisely change the DC voltage applied to the edge ring 112a by the DC power source 200 according to the second time t2.

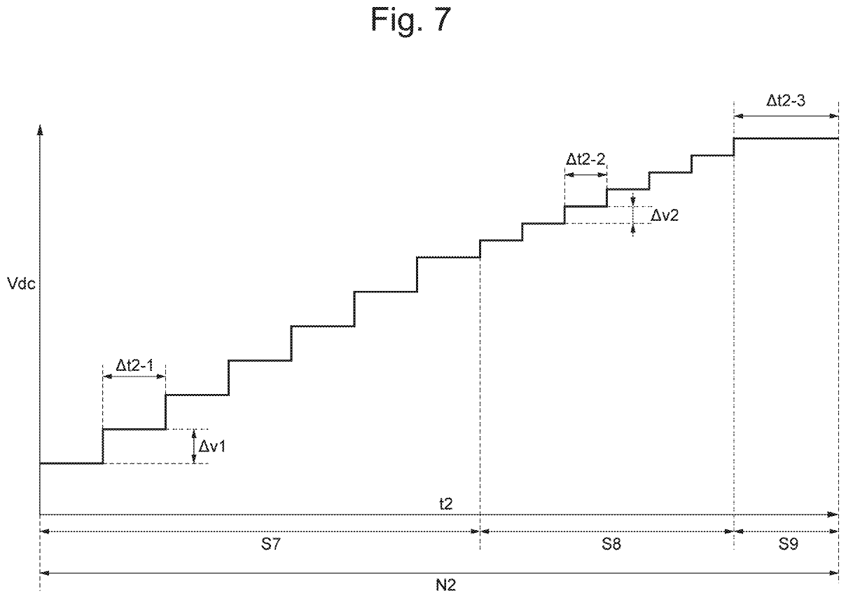

In the example illustrated in FIG. 7, the second processor 253 is configured to stepwisely increase the DC voltage Vdc according to the second time t2. Specifically, the second processor 253 is configured to add a first voltage value Δv1 to the voltage level of the DC voltage Vdc in each step in the first section S7. The second processor 253 is configured to add a second voltage value Δv2 different from the first voltage value Δv1 to the voltage level of the DC voltage Vdc in each step in the second section S8. The second processor 253 is configured to maintain a constant voltage level in the third section S9. In each of the sections S7 to S9, the voltage values Δv1 and Δv2 to be increased in each step, the times (lengths) Δt2-1, Δt2-2, and Δt2-3 of each step, and the number of steps may be set, respectively. A combined time of the sections S7 to S9 may be the replacement cycle N2 of the edge ring 112a. The number of sections is not limited to three, and the number of sections may be one or two, or four or more.

### <Example of Plasma Processing Method>

The plasma processing method includes etching processing in which a film on the substrate W is etched using plasma. In one embodiment, the plasma processing method is performed by the controller 2 in the plasma processing apparatus 1.

First, the substrate W is transported into the chamber 10 by a transport arm, placed on the substrate support 11 by a lifter, and held in place by suction on the substrate support 11 as illustrated in FIG. 2.

Next, plasma is generated in the plasma processing space 10s by the plasma generator 12. First, the processing gas is supplied to the shower head 13 by the gas supply 20, and then is supplied from the shower head 13 to the plasma processing space 10s. The processing gas supplied at this time includes a gas that generates active species necessary for etching processing of the substrate W. The processing gas includes the first gas.

RF power is supplied from the RF power source 31 to the upper electrode 13d and/or the lower electrode. The DC voltage is applied from the DC power source 200 to the edge ring 112a. The atmosphere in the plasma processing space 10s is exhausted from the gas exhaust port 10e, and the inside of the plasma processing space 10s is depressurized. Plasma is generated from the processing gas on the substrate support 11 of the plasma processing space 10s, and the substrate W is etched.

In the plasma processing apparatus 1, the etching processing described above is continuously performed on multiple substrates. This continuous etching processing may include not only processing using the same recipe, but also processing using different recipes. The first counter 250 counts the first time t1 according to the operation time of the RF power source 31. In one embodiment, the first counter 250 counts the time during which the RF power source 31 supplies RF power to the upper electrode 13d or the lower electrode as the first time t1. Then, as illustrated in FIG. 4, when the first time t1 reaches the replacement cycle N1, the upper electrode 13d is replaced with a new one. In this case, the first time t1 is reset (to the reference value), and the count of the first time t1 is started again from the reference value for the new upper electrode 13d. The reference value may be zero.

As illustrated in FIG. 5, the first processor 252 stepwisely increases the RF power Prf supplied to the upper electrode 13d or the lower electrode by the RF power source 31 according to the first time t1. That is, as the usage time (time exposed to plasma) of the upper electrode 13d in plasma processing increases, the RF power Prf is gradually increased. In this case, in each of the sections S1 to S3, the power values Δp1 and Δp2 to be increased in each step, the times (lengths) Δt1-1, Δt1-2, Δt1-3 of each step, and the number of steps may be set. The power value to be increased in each step, the time in each step, and the number of steps may decrease as the first time t1 progresses (as the sections S1 to S3 progress). By doing so, even if the upper electrode 13d is gradually worn down, the density of plasma generated in the chamber 10 is maintained within a predetermined range, and as a result, a line width (CD) of the etching target film in the etching processing is maintained within an appropriate range.

As illustrated in FIG. 6, the first processor 252 stepwisely decreases the flow rate F1 of the first gas supplied to the chamber 10 by the gas supply 20 according to the first time t1. That is, as the usage time (time exposed to plasma) of the upper electrode 13d in the plasma processing increases, the flow rate F1 of the first gas is gradually decreased. In this case, in each of the sections S4 to S6, the flow rate values Δf1-1 and Δf1-2 to be subtracted in each step, the times (lengths) Δt1-1, Δt1-2, and Δt1-3 of each step, and the number of steps may be set, respectively. The flow rate value to be decreased in each step, the time in each step, and the number of steps may decrease as the first time t1 progresses (as the sections S4 to S6 progress). By doing so, even if the upper electrode 13d is gradually worn down, the line width (CD) of the etching target film in the etching processing is maintained within an appropriate range.

The second counter 251 counts the second time t2 according to the operation time of the RF power source 31. In one embodiment, the second counter 251 counts the time during which the RF power source 31 supplies RF power to the upper electrode 13d or the lower electrode as the second time t2. Then, as illustrated in FIG. 4, when the second time t2 reaches the replacement cycle N2, the edge ring 112a is replaced with a new one. In this case, the second time t2 is reset (to the reference value), and the count of the second time t2 is started again from the reference value for the new edge ring 112a. The reference value may be zero.

As illustrated in FIG. 7, the second processor 253 stepwisely increases the DC voltage Vdc applied to the edge ring 112a by the DC power source 200 according to the second time t2. That is, as the usage time (time exposed to plasma) of the edge ring 112a in the plasma processing increases, the DC voltage Vdc is gradually increased. In this case, in each of the sections S7 to S9, the voltage values Δv1 and Δv2 to be increased in each step, the times (lengths) Δt2-1, Δt2-2, and Δt2-3 of each step, and the number of steps may be set, respectively. The voltage value to be increased in each step, the time of each step, and the number of steps may decrease as the second time t2 progresses (as sections S7 to S9 progress). By doing so, even if the edge ring 112a is gradually worn down, the inclination of the sheath on the outer periphery of the substrate W is maintained within a predetermined range, and as a result, the tilting angle on the outer periphery of the substrate W in the etching processing is maintained within an appropriate range.

According to this exemplary embodiment, the plasma processing apparatus 1 includes the first counter 250 configured to count the first time t1 according to the operation time of the RF power source 31 and to reset the first time t1 by replacing the upper electrode 13d; the second counter 251 configured to count the second time t2 according to the operation time of the RF power source 31 and to reset the second time t2 by replacing the edge ring 112a; the first processor 252 configured to stepwisely change at least one of the RF power and the flow rate of the first gas according to the first time t1; and the second processor 253 configured to stepwisely change the DC voltage according to the second time t2. As a result, the RF power and the process parameter of the first gas can be stepwisely changed according to the amount of use of the upper electrode 13d calculated from the time of replacement, and the process parameter of the DC voltage can be stepwisely changed according to the amount of use of the edge ring 112a calculated from the time of replacement. As a result, in the plasma processing apparatus 1, it is possible to reduce an influence on the plasma processing of the substrate due to the wear of components in the chamber 10.

### Second Embodiment

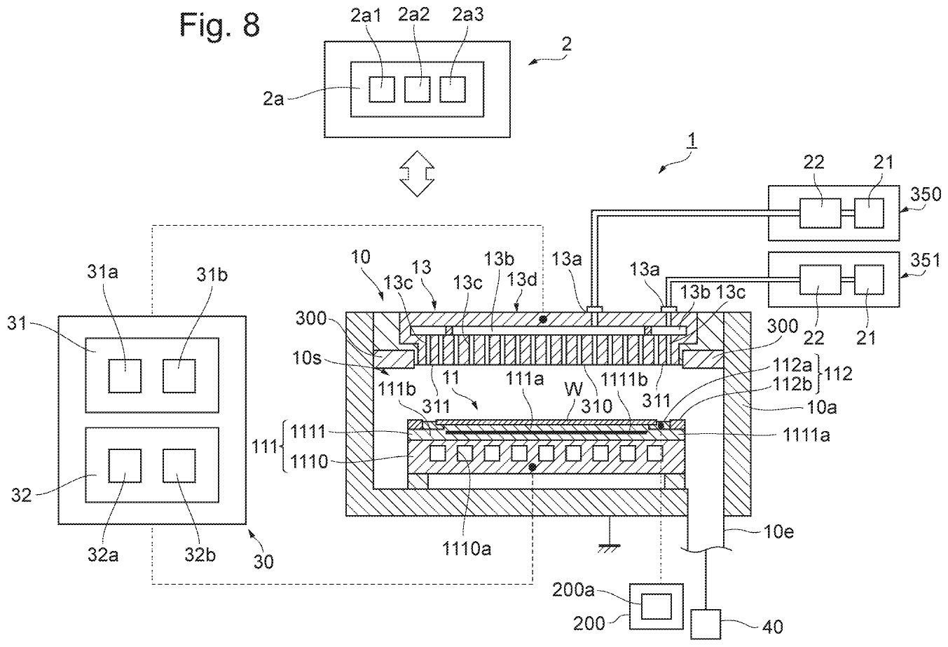

In the example illustrated in FIG. 8, the plasma processing apparatus 1 includes an upper annular member 300 placed to surround the upper electrode 13d. The upper electrode 13d has a central region 310 and an annular region 311. The plasma processing apparatus 1 illustrated in FIG. 8 includes a first gas supply 350 configured to supply the first gas into the chamber 10 via the central region 310, and a second gas supply 351 configured to supply the second gas into the chamber 10 via the annular region 311.

The upper annular member 300 is electrically insulated from the upper electrode 13d. In one embodiment, the upper annular member 300 is made of a silicon material. The upper annular member 300 is electrically connected to a ground potential via the sidewall 10a of the chamber 10.

The annular region 311 of the upper electrode 13d is placed to surround the central region 310. The central region 310 and the annular region 311 have the gas supply port 13a, the gas diffusion chamber 13b, and a gas introduction port 13c for the shower head 13, respectively. The central region 310 may be placed to face the central region 111a of the substrate support 11, and the annular region 311 may be placed to face the ring assembly 112.

The first gas supply 350 and the second gas supply 351 may have the same configuration as the gas supply 20 described in the first embodiment. The second gas supply 351 may include at least one gas source 21 and at least one flow rate controller 22. The first gas supplied by the first gas supply 350 and the second gas supplied by the second gas supply 351 may be gases that generate plasma. The second gas may contain the same type of gas as the first gas, but in different flow rate ratios.

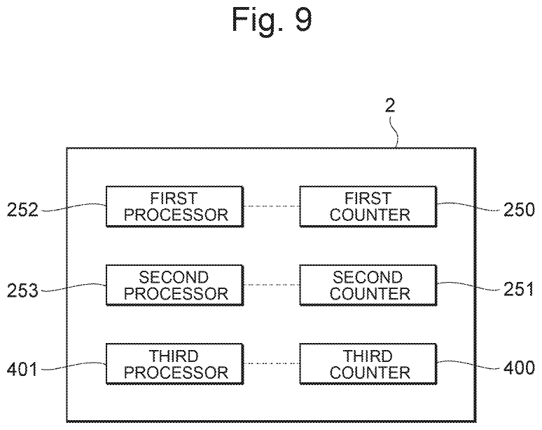

As illustrated in FIG. 9, in one embodiment, the plasma processing apparatus 1 may further include a third counter 400 and a third processor 401. The third counter 400 and the third processor 401 may be included in the controller 2.

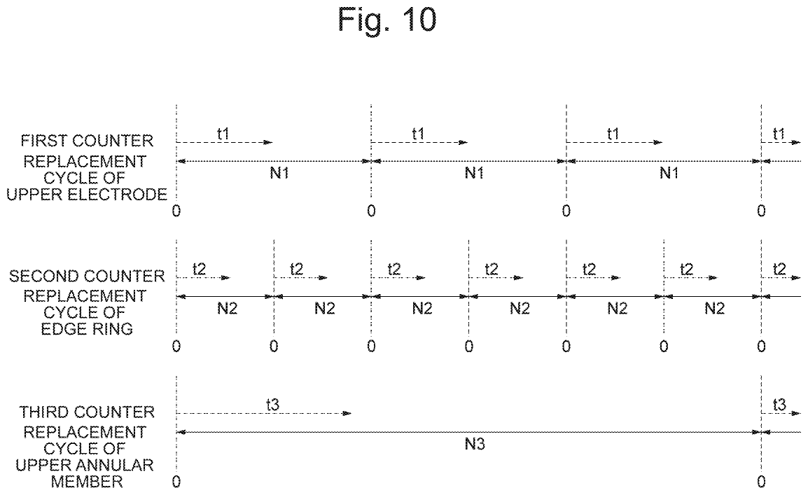

As illustrated in FIG. 10, the third counter 400 is configured to count a third time t3 according to the operation time of the RF power source 31 and to reset the third time t3 by replacing the upper annular member 300. That is, the third time t3 of the third counter 400 is reset each time the upper annular member 300 is replaced, and then is counted from the reference value according to the operation time of the RF power source 31. The reference value may be zero.

A replacement cycle N3 of the upper annular member 300 is different from the replacement cycle N1 of the upper electrode 13d and the replacement cycle N2 of the edge ring 112a. In one embodiment, the replacement cycle N3 of the upper annular member 300 is longer than the replacement cycle N1 of the upper electrode 13d and the replacement cycle N2 of the edge ring 112a. In this case, the third time t3 counted by the third counter 400 is reset at a longer interval than the first time t1 counted by the first counter 250 and the second time t2 counted by the second counter 251.

In one embodiment, the third processor 401 is configured to stepwisely change the flow rate of the second gas supplied to the chamber 10 by the second gas supply 351 according to the third time t3.

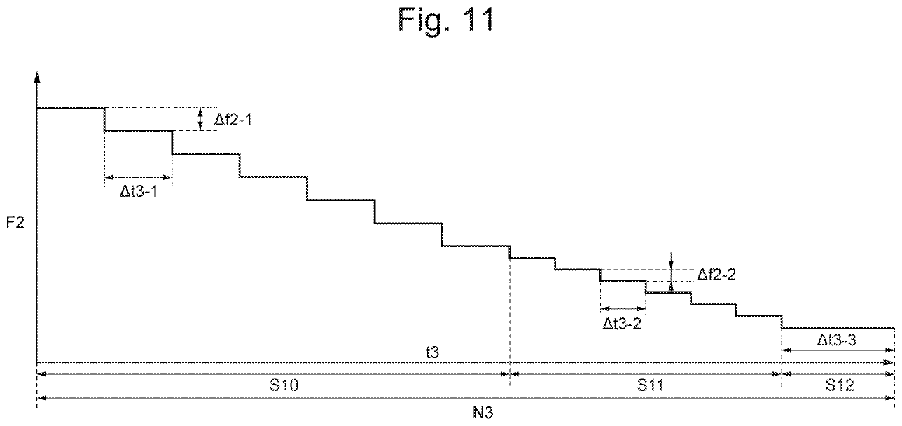

In the example illustrated in FIG. 11, the third processor 401 is configured to stepwisely reduce the flow rate F2 of the second gas according to the third time t3. Specifically, the third processor 401 is configured to subtract a first flow rate value Δf2-1 from the flow rate F2 of the second gas in each step in the first section S10. The third processor 401 is configured to subtract a second flow rate value Δf2-2 different from the first flow rate value Δf2-1 from the flow rate F2 of the second gas in each step in the second section S11. The third processor 401 is configured to maintain a constant flow rate in the third section S12. In each of the sections S10 to S12, the flow rate values Δf2-1 and Δf2-2 to be subtracted in each step, the times (lengths) Δt3-1, Δt3-2, and Δt3-3 of each step, and the number of steps may be set, respectively. A combined time of the sections S10 to S12 may be the replacement cycle N3 of the upper annular member 300. The number of sections is not limited to three, and the number of sections may be one or two, or four or more. Other components of the plasma processing apparatus 1 in the second embodiment may be the same as those in the first embodiment.

In the plasma processing apparatus 1, the etching processing is continuously performed on multiple substrates in the same manner as in the first embodiment. In this case, the third counter 400 counts the third time t3 according to the operation time of the RF power source 31. The third counter 400 counts the time during which the RF power source 31 supplies RF power to the upper electrode 13d or the lower electrode as the third time t3. Then, as illustrated in FIG. 10, when the third time t3 reaches the replacement cycle N3, the upper annular member 300 is replaced with a new one. In this case, the third time t3 is reset (to the reference value), and the count of the third time t3 is started again from the reference value for the new upper annular member 300. The reference value may be zero.

As illustrated in FIG. 11, the third processor 401 stepwisely decreases the flow rate F2 of the second gas supplied to the chamber 10 by the second gas supply 351 according to the third time t3. That is, as the usage time (time exposed to plasma) of the upper annular member 300 in the plasma processing increases, the flow rate F2 of the second gas is gradually decreased. In this case, in each of the sections S10 to S12, the flow rate values Δf2-1 and Δf2-2 to be subtracted in each step, the times (lengths) Δt3-1, Δt3-2, and Δt3-3 of each step, and the number of steps may be set, respectively. The flow rate value to be decreased in each step, the time in each step, and the number of steps may decrease as the third time t3 progresses (as the sections S10 to S12 progress). By doing so, even if the upper annular member 300 is gradually worn down, the line width (CD) of the etching target film in the etching processing is maintained within an appropriate range.

The operation of the first counter 250, the second counter 251, the first processor 252, and the second processor 253 of the plasma processing apparatus 1 may be performed in the same manner as in the first embodiment. That is, the count of the first time t1 by the first counter 250, the change of the RF power Prf according to the first time t1 by the first processor 252, and the change of the flow rate F1 of the first gas by the first processor 252 may be performed in the same manner as in the first embodiment described above. The count of the second time t2 by the second counter 251 and the change of the DC voltage Vdc by the second processor 253 according to the second time t2 may be performed in the same manner as in the first embodiment described above.

In the second embodiment, the third counter 400 resets the third time t3 by replacing the upper annular member 300, and the third processor 401 changes the flow rate F2 of the second gas according to the usage time (third time t3) of the upper annular member 300, but the third counter 400 may reset the third time t3 by replacing the cover ring 112b as the annular member, and the third processor 401 may change the flow rate F2 of the second gas according to the usage time (third time t3) of the cover ring 112b in the plasma processing.

In the second embodiment, the first processor 252 may be configured to stepwisely change the RF power supplied to the upper electrode 13d or the lower electrode by the RF power source 31 according to the first time t1 and the third time t3. That is, the first processor 252 may stepwisely change the RF power based on the first time t1 based on the usage time of the upper electrode 13d and the third time t3 based on the usage time of the upper annular member 300.

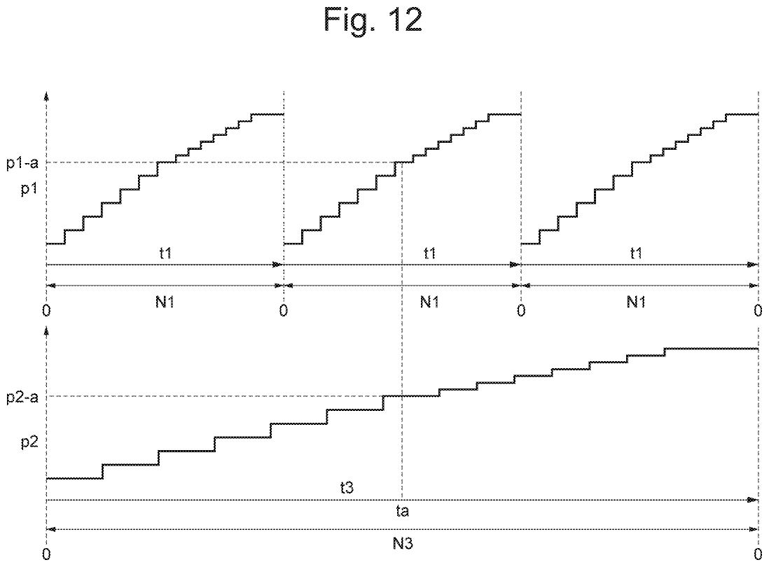

In this case, as illustrated in FIG. 12, the first processor 252 is configured to add a first power value p1 according to the first time t1 and a second power value p2 according to the third time t3 to the power level of the RF power Prf. Here, the first power value p1 stepwisely increases according to the first time t1, and the second power value p2 stepwisely increases according to the third time t3. For example, at a certain time Ta, when the first power value p1 is “p1-a” and the second power value p2 is “p2-a”, “p1-a” and “p2-a” may be added to the power level of the RF power Prf. In this example, the RF power can be appropriately adjusted based on multiple usage times of multiple consumable components.

In the first and second embodiments described above, the first counter 250 resets the first time t1 by replacing the upper electrode 13d and counts the usage time of the upper electrode 13d, but may reset the first time t1 by replacing other first consumable components other than the upper electrode 13d and count the usage time of the other first consumable components. The second counter 251 resets the second time t2 by replacing the edge ring 112a and counts the usage time of the edge ring 112a, but may reset the second time t2 by replacing other second consumable components other than the edge ring 112a and count the usage time of the other second consumable components. The third counter 400 resets the third time t3 by replacing the upper annular member 300 or the cover ring 112b and counts the usage time of the upper annular member 300 or the cover ring 112b but may reset the third time t3 by replacing other third consumable components other than the upper annular member 300 or the cover ring 112b and count the usage time of the other third consumable components. In the embodiments described above, the processor changes the RF power, the DC voltage, the flow rate of the first gas, and the flow rate of the second gas according to the time counted by the counter, but may change other process parameters. The process parameters may include bias power supplied to the lower electrode, a pulsed voltage applied to the lower electrode, a temperature of the substrate support or the substrate, the DC voltage applied to the upper electrode, and the like.

The number of counters, such as the first to third counters 250, 251, and 400 which are configured to count the time according to the operation time of the RF power source and in which the time is reset by replacing consumable components, and the number of processors, such as the first to third processors 252, 253, and 401 which are configured to stepwisely change the process parameters according to the time counted by the counter, may be one or four or more.

The number of sections in which the processor stepwisely changes the process parameters according to the time counted by the counter may be one, two, three, or four or more. In each section, the value to be added to or subtracted from the process parameters in each step may be manually input and set in the processor. The number of sections and the time (length) of each section may be manually input and set in the processor.

In the embodiments described above, the usage time of consumable components is counted according to the operation time of the RF power source, and the process parameters are changed according to the usage time, but the number of substrates to be processed may be counted, and the process parameters may be changed according to the number of substrates to be processed. That is, the first counter is configured to count the first number of substrates to be processed according to the operation time of the RF power source, and the first number of substrates to be processed is configured to be reset by replacing the first consumable component, the second counter is configured to count the second number of substrates to be processed according to the operation time of the RF power source, and the second number of substrates to be processed is configured to be reset by replacing the second consumable component, the first processor is configured to stepwisely change the first process parameter according to the first number of substrates to be processed, and the second processor may be configured to stepwisely change the second process parameter according to the second number of substrates to be processed.

In the embodiments described above, the plasma processing apparatus is not limited to the capacitively-coupled plasma processing apparatus, but may be other types of plasma processing apparatus, such as a plasma processing apparatus that generates an inductively-coupled plasma, a plasma processing apparatus that generates an ECR plasma, a plasma processing apparatus that generates a helicon wave excited plasma, or a plasma processing apparatus that generates a surface wave plasma.

In the embodiments described above, the time is counted according to the operation time of the RF power source, but is not limited thereto. For example, the time may be counted according to various counters built into the plasma processing apparatus 1.

In the embodiments described above, the plasma processing apparatus 1 is described as an example, but is not limited thereto. For example, the plasma processing apparatus 1 may also be applied to a substrate processing apparatus that does not use plasma. In this case, the substrate processing apparatus includes the chamber, the first consumable component placed within the chamber, and the second consumable component placed within the chamber. The substrate processing apparatus further includes the first counter, the second counter, the first processor, and the second processor. The first counter is configured to count the first time according to the operation time of the substrate processing apparatus and to reset the first time by replacing the first consumable component. The second counter is configured to count the second time according to the operation time of the substrate processing apparatus and to reset the second time by replacing the second consumable component. The first processor is configured to stepwisely change the first process parameter according to the first time. The second processor is configured to stepwisely change the second process parameter according to the second time.

In one embodiment, the substrate processing apparatus includes the chamber and the consumable component placed within the chamber. Furthermore, the substrate processing apparatus further includes the counter and the processor. The counter is configured to count the first time according to the operation time of the substrate processing apparatus and to reset the first time by replacing the consumable component. The processor is configured to stepwisely change the first process parameter according to the first time. Specifically, the processor is configured to add or subtract the first value to or from the first process parameter in each step in the first section, and to add or subtract the second value to or from the first process parameter in each step in the second section. The operation time of the substrate processing apparatus may be obtained based on various counters built into the substrate processing apparatus.

Embodiments of the present disclosure further include the following aspects.

### (Aspect 1)

A plasma processing apparatus including:
a chamber;
a substrate support placed within the chamber and including a lower electrode;
an edge ring placed to surround a substrate on the substrate support;
an upper electrode placed above the substrate support;
a first gas supply configured to supply a first gas into the chamber;
an RF power source configured to supply RF power to the upper electrode or the lower electrode to generate plasma from the first gas within the chamber;
a DC power source configured to apply a DC voltage to the edge ring;
a first counter configured to count a first time according to an operation time of the RF power source and to reset the first time by replacing the upper electrode;
a second counter configured to count a second time according to the operation time of the RF power source and to reset the second time by replacing the edge ring;
a first processor configured to stepwisely change at least one of the RF power and the first gas according to the first time; and
a second processor configured to stepwisely change the DC voltage according to the second time.

### (Aspect 2)

The plasma processing apparatus according to Aspect 1, in which a replacement cycle of the edge ring is different from a replacement cycle of the upper electrode.

(aspect 3)

The plasma processing apparatus according to Aspect 1 or 2, in which the first processor is configured to stepwisely increase the RF power according to the first time, and
the second processor is configured to stepwisely increase the DC voltage according to the second time.
   (aspect 4)

The plasma processing apparatus according to any one of Aspects 1 to 3, in which the first processor is configured to stepwisely decrease a flow rate of the first gas according to the first time.

(aspect 5)

The plasma processing apparatus according to any one of Aspects 1 to 4, further including:
a second gas supply,
in which the upper electrode has a central region and an annular region in a plan view,
the first gas supply is configured to supply the first gas into the chamber via the central region; and
the second gas supply is configured to supply a second gas into the chamber via the annular region.

### (Aspect 6)

The plasma processing apparatus according to Aspect 5, further including:
an annular member placed to surround the upper electrode or the edge ring;
a third counter configured to count a third time according to the operation time of the RF power source and to reset the third time by replacing the annular member; and
a third processor configured to stepwisely change a flow rate of the second gas according to the third time.
   (aspect 7)

The plasma processing apparatus according to any one of Aspects 1 to 6, further including:
an annular member placed to surround the upper electrode; and
a third counter configured to count a third time according to the operation time of the RF power source and to reset the third time by replacing the annular member,
in which the first processor is configured to stepwisely change the RF power according to the first time and the third time.

### (Aspect 8)

The plasma processing apparatus according to Aspect 7, in which the first processor is configured to add a first power value according to the first time and a second power value according to the third time to a power level of the RF power.

### (Aspect 9)

The plasma processing apparatus according to any one of Aspects 1 to 8, in which the first processor is configured to add a first power value to a power level of the RF power in each step in a first section, and to add a second power value different from the first power value to the power level of the RF power in each step in a second section.

### (Aspect 10)

The plasma processing apparatus according to Aspect 9, in which the first processor is configured to maintain a constant power level in a third section.

### (Aspect 11)

The plasma processing apparatus according to any one of Aspects 1 to 10, in which the second processor is configured to add a first voltage value to a voltage level of the DC voltage in each step in a first section, and to add a second voltage value different from the first voltage value to the voltage level of the DC voltage in each step in a second section.

### (Aspect 12)

The plasma processing apparatus according to Aspect 11, in which the second processor is configured to maintain a constant voltage level in a third section.

### (Aspect 13)

The plasma processing apparatus according to any one of Aspects 1 to 12, in which the first processor is configured to subtract a first flow rate value from a flow rate of the first gas in each step in a first section, and to subtract a second flow rate value different from the first flow rate value from the flow rate of the first gas in each step in a second section.

(aspect 14)

The plasma processing apparatus according to Aspect 13, in which the first processor is configured to maintain a constant flow rate in a third section.

(aspect 15)

A plasma processing apparatus including:
a chamber;
an RF power source configured to generate RF power to generate plasma within the chamber;
a first consumable component placed within the chamber;
a second consumable component placed within the chamber;
a first counter configured to count a first time according to an operation time of the RF power source and to reset the first time by replacing the first consumable component;
a second counter configured to count a second time according to the operation time of the RF power source and to reset the second time by replacing the second consumable component;
a first processor configured to stepwisely change a first process parameter according to the first time; and
a second processor configured to stepwisely change a second process parameter according to the second time.

### (Aspect 16)

The plasma processing apparatus according to Aspect 15, in which a replacement cycle of the first consumable component is different from a replacement cycle of the second consumable component.

### (Aspect 17)

The plasma processing apparatus according to Aspect 15 or 16, further including:
a third consumable component placed within the chamber; and
a third counter configured to count a third time according to the operation time of the RF power source and to reset the third time by replacing the third consumable component,
in which the first processor is configured to add or subtract a first value according to the first time and a second value according to the third time to or from the first process parameter.

### (Aspect 18)

The plasma processing apparatus according to any one of Aspects 15 to 17, in which the first processor is configured to add or subtract a first value to or from the first process parameter in each step in a first section, and to add or subtract a second value to or from the first process parameter in each step in a second section.

### (Aspect 19)

The plasma processing apparatus according to any one of Aspects 15 to 18, in which the second processor is configured to add or subtract a first value to or from the second process parameter in each step in a first section, and to add or subtract a second value to or from the second process parameter in each step in a second section.

### (Aspect 20)

A plasma processing apparatus including:
a chamber;
an RF power source configured to generate RF power to generate plasma within the chamber;
a consumable component placed within the chamber;
a counter configured to count a first time according to an operation time of the RF power source and to reset the first time by replacing the consumable component; and
a processor configured to stepwisely change a first process parameter according to the first time,
n which the processor is configured to
   add or subtract a first value to or from the first process parameter in each step in a first section, and add or subtract a second value to or from the first process parameter in each step in a second section.

In the exemplary embodiments described above, the plasma processing apparatus can be modified in various ways without departing from the scope and spirit of the disclosure. For example, within the scope of the ordinary creative ability of a person skilled in the art, some components of one embodiment can be added to other embodiments. Furthermore, some components in one embodiment can be replaced with corresponding components in another embodiment.

According to one exemplary embodiment of the present disclosure, it is possible to provide a technique that can reduce an influence on plasma processing of a substrate due to the wear of components in a chamber of a plasma processing apparatus.

What is claimed is

1. A plasma processing apparatus comprising:
a chamber;
a substrate support placed within the chamber and including a lower electrode;
an edge ring placed to surround a substrate on the substrate support;
an upper electrode placed above the substrate support;
a first gas supply configured to supply a first gas into the chamber;
an RF power source configured to supply RF power to the upper electrode or the lower electrode to generate plasma from the first gas within the chamber;
a DC power source configured to apply a DC voltage to the edge ring;
a first counter configured to count a first time according to an operation time of the RF power source and to reset the first time by replacing the upper electrode;
a second counter configured to count a second time according to the operation time of the RF power source and to reset the second time by replacing the edge ring;
a first processor configured to stepwisely change at least one of the RF power and the first gas according to the first time; and
a second processor configured to stepwisely change the DC voltage according to the second time.

2. The plasma processing apparatus according to claim 1, wherein a replacement cycle of the edge ring is different from a replacement cycle of the upper electrode.

3. The plasma processing apparatus according to claim 2, wherein the first processor is configured to stepwisely increase the RF power according to the first time, and
the second processor is configured to stepwisely increase the DC voltage according to the second time.

4. The plasma processing apparatus according to claim 2, wherein the first processor is configured to stepwisely decrease a flow rate of the first gas according to the first time.

5. The plasma processing apparatus according to claim 1, further comprising:
a second gas supply,
wherein the upper electrode has a central region and an annular region in a plan view,
the first gas supply is configured to supply the first gas into the chamber via the central region, and
the second gas supply is configured to supply a second gas into the chamber via the annular region.

6. The plasma processing apparatus according to claim 5, further comprising:
an annular member placed to surround the upper electrode or the edge ring;
a third counter configured to count a third time according to the operation time of the RF power source and to reset the third time by replacing the annular member; and
a third processor configured to stepwisely change a flow rate of the second gas according to the third time.

7. The plasma processing apparatus according to claim 1, further comprising:
an annular member placed to surround the upper electrode; and
a third counter configured to count a third time according to the operation time of the RF power source and to reset the third time by replacing the annular member,
wherein the first processor is configured to stepwisely change the RF power according to the first time and the third time.

8. The plasma processing apparatus according to claim 7, wherein the first processor is configured to add a first power value according to the first time and a second power value according to the third time to a power level of the RF power.

9. The plasma processing apparatus according to claim 1, wherein the first processor is configured to add a first power value to a power level of the RF power in each step in a first section, and to add a second power value different from the first power value to the power level of the RF power in each step in a second section.

10. The plasma processing apparatus according to claim 9, wherein the first processor is configured to maintain a constant power level in a third section.

11. The plasma processing apparatus according to claim 1, wherein the second processor is configured to add a first voltage value to a voltage level of the DC voltage in each step in a first section, and to add a second voltage value different from the first voltage value to the voltage level of the DC voltage in each step in a second section.

12. The plasma processing apparatus according to claim 11, wherein the second processor is configured to maintain a constant voltage level in a third section.

13. The plasma processing apparatus according to claim 1, wherein the first processor is configured to subtract a first flow rate value from a flow rate of the first gas in each step in a first section, and to subtract a second flow rate value different from the first flow rate value from the flow rate of the first gas in each step in a second section.

14. The plasma processing apparatus according to claim 13, wherein the first processor is configured to maintain a constant flow rate in a third section.

15. A plasma processing apparatus comprising:
a chamber;
an RF power source configured to generate RF power to generate plasma within the chamber;
a first consumable component placed within the chamber;
a second consumable component placed within the chamber;
a first counter configured to count a first time according to an operation time of the RF power source and to reset the first time by replacing the first consumable component;
a second counter configured to count a second time according to the operation time of the RF power source and to reset the second time by replacing the second consumable component;
a first processor configured to stepwisely change a first process parameter according to the first time; and
a second processor configured to stepwisely change a second process parameter according to the second time.

16. The plasma processing apparatus according to claim 15, wherein a replacement cycle of the first consumable component is different from a replacement cycle of the second consumable component.

17. The plasma processing apparatus according to claim 16, further comprising:
a third consumable component placed within the chamber; and
a third counter configured to count a third time according to the operation time of the RF power source and to reset the third time by replacing the third consumable component,
wherein the first processor is configured to add or subtract a first value according to the first time and a second value according to the third time to or from the first process parameter.

18. The plasma processing apparatus according to claim 16, wherein the first processor is configured to add or subtract a first value to or from the first process parameter in each step in a first section, and to add or subtract a second value to or from the first process parameter in each step in a second section.

19. The plasma processing apparatus according to claim 16, wherein the second processor is configured to add or subtract a first value to or from the second process parameter in each step in a first section, and to add or subtract a second value to or from the second process parameter in each step in a second section.

20. A plasma processing apparatus comprising:
a chamber;
an RF power source configured to generate RF power to generate plasma within the chamber;
a consumable component placed within the chamber;
a counter configured to count a first time according to an operation time of the RF power source and to reset the first time by replacing the consumable component; and
a processor configured to stepwisely change a first process parameter according to the first time,
wherein the processor is configured to add or subtract a first value to or from the first process parameter in each step in a first section, and to add or subtract a second value to or from the first process parameter in each step in a second section.
